(19) United States
(12) Patent Application Publication
(10) Pub. No.: US 2004/0195683 A1
(43) Pub. Date: Oct. 7, 2004

(54) Compact electronic device and package used therefor

(75) Inventors: Naoyuki Mishima, Yokohama (JP); Takamasa Oto, Itami (JP)

Correspondence Address: ARENT FOX KINTNER PLOTKIN & KAHN, PLLC, Suite 400, 1050 Connecticut Avenue, N.W., Washington, DC, 20036-5339, US

(73) Assignees: Fujitsu Media Devices Limited; Fujimaru Industry Co., Ltd.

(21) Appl. No.: 10/809,887

(22) Filed: Mar. 26, 2004

(30) Foreign Application Priority Data
Apr. 3, 2003 (JP) 2003-099964

(51) Int. Cl. H01L 23/544

(52) U.S. Cl. 257/725

(57) ABSTRACT

An electronic device includes a package having a metal part shaped by pressing a metal member, and an insulator part bonded to the metal part through fusing. A chip is housed in the package. First terminals are electrically connected to the chip and are buried in the insulator part so as to be arranged in a line. A plate member supports the chip from the backside thereof. The metal parts have recess portions that define second external terminals. The plate member is provided so as to cover the recess portions.

### BACKGROUND OF THE INVENTION

1. Field of the Invention

The invention generally relates to compact electronic devices having a package that hermetically seals a chip, and more particularly, to an electronic device having a package structure suitable for hermetically sealing a surface acoustic wave chip.

2. Description of the Related Art

A conventional surface acoustic wave (SAW) device is composed of a SAW chip and a package for hermetically sealing the SAW chip. The SAW device is used as a filter device or an oscillation element built in television sets (TV), video tape recorders (VTR), digital versatile disks (DVD) and cellular phones. More specifically, the SAW device is widely used for various circuits that handle RF signals in the frequency range of 45 MHz to 2 GHz. Examples of such circuits are a transmit band-pass filter, a receive band-pass filter, a local oscillation filter, an antenna duplexer, an intermediate frequency filter and a frequency modulator.

Recently, electronic equipment has been considerably downsized and there has been a strong demand to downsize the electronic parts such as SAW devices. Particularly, portable equipment such as a cellular phone needs a surface-mountable, thin SAW device.

Japanese Patent Application Publication No. 7-336186 discloses a ceramic package for realizing surface mounting in the SAW device. However, the use of the ceramic package results in the costly SAW device, particularly when it has a relatively large size.

In contrast, Japanese Patent Application Publication No. 2001-60842 discloses a less-expensive package structure realized in the absence of ceramics. The package structure is composed of a metal part and an insulator part. The insulator part is provided in through holes formed in the metal part. Lead electrodes for making external connections are buried in the insulator part. A quartz crystal resonator housed in the package is supported at both ends thereof in order to restrict vibration.

However, the package disclosed in Publication '842 is not suitable for a die-mounted chip such as the SAW chip because it supports the both ends of the quartz crystal resonator. In addition, the package has a difficulty in downsizing. This is because all lead electrodes buried in the insulator part penetrate the through holes formed in the metal part.

### SUMMARY OF THE INVENTION

It is an object of the present invention to provide a compact electronic device equipped with a surface-mounted chip and a package suitable for such an electronic device.

According to an aspect of the present invention, there is provided an electronic device comprising: a package having a metal part shaped by pressing a metal member, and an insulator part bonded to the metal part through fusing; a chip housed in the package; first terminals electrically connected to the chip and buried in the insulator part so as to be arranged in a line; and a plate member that supports the chip from a backside thereof, the metal parts having recess portions that define second external terminals, the plate member being provided so as to cover the recess portions.

According to another aspect of the present invention, there is provided a package having a metal part shaped by pressing a metal member, and an insulator part bonded to the metal part through fusing; a chip housed in the package; first terminals electrically connected to the chip and buried in the insulator part so as to be arranged in a line; and second terminals attached to an outer surface of the metal part, the chip being attached to an inner surface of the metal surface and facing the second external terminals through the metal part.

According to yet another aspect of the present invention, there is provided a package comprising: a metal part shaped by pressing a metal member; an insulator part bonded to the metal part through fusing; first terminals electrically connected to a chip and buried in the insulator part so as to be arranged in a line; and a plate member that supports the chip from a backside thereof, the metal parts having recess portions that define second external terminals, the plate member being provided so as to cover the recess portions.

According to a further aspect of the present invention, there is provided a package comprising: a metal part shaped by pressing a metal member; an insulator part bonded to the metal part through fusing; first terminals electrically connected to a chip and buried in the insulator part so as to be arranged in a line; and second terminals attached to an outer surface of the metal part, the chip being attached to an inner surface of the metal surface and facing the second external terminals through the metal part.

### BRIEF DESCRIPTION OF THE DRAWINGS

Preferred embodiments of the present invention will be described in detail based on the following figures, wherein:

FIG. 1A is a plan view of a comparative SAW device seen through a cap;

FIG. 1B is a bottom view of the comparative SAW device;

FIG. 1C is a cross-section taken along a line A-A′ shown in FIGS. 1A and 1B;

FIG. 1D is a plan view of a SAW chip of the comparative SAW device shown in FIG. 1A;

FIG. 2A shows a plan view of a package of a SAW device according to a first embodiment of the present invention;

FIG. 2B is a plan view of the SAW device while seeing through the cap according to the first embodiment;

FIG. 2C is a bottom view of the SAW device according to the first embodiment;

FIG. 2D is a cross-sectional view taken along a line B-B′ shown in FIG. 2B;

FIG. 3A shows a plan view of a package of the SAW device according to a second embodiment of the present invention.

FIG. 3B shows the inside of the SAW device while seeing through a cap;

FIG. 3C is a bottom view of the SAW device;

FIG. 3D is a cross-sectional view taken along a line that corresponds to the line C-C′ in FIG. 3B;

FIG. 4A is a plan view of a SAW device in a state in which the cap has been removed according to a third embodiment of the present invention; and

FIG. 4B is a cross-sectional view taken along a line running in the short-side direction.

### DESCRIPTION OF THE PREFERRED EMBODIMENTS

In order to facilitate better understanding of the present invention, a description will now be given of a comparative SAW device. This SAW device employs a package composed of a metal part obtained by processing a metal member, and an insulator part fixed thereto through fusing.

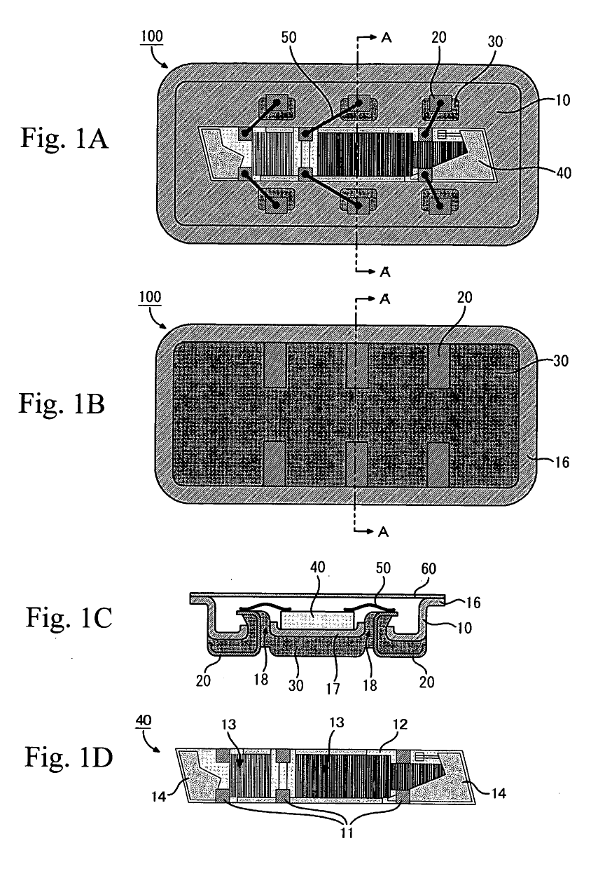

FIGS. 1A through 1D show the comparative SAW device. More particularly, FIG. 1A is a plan view of the comparative SAW device seen through a cap that will be described later. FIG. 1B is a bottom view of the comparative SAW device. FIG. 1C is a cross-section taken along a line A-A′ shown in FIGS. 1A and 1B. FIG. 1D is a plan view of a SAW chip of the comparative SAW device shown in FIG. 1A.

The comparative SAW device has a package 100 and a SAW chip 40, which is hermetically sealed within the package 100. The package 100 has a metal part 10 and an insulator part 30. The SAW chip 40 is housed in a cavity of the package 100. A metal member is shaped into the metal part 10 by press. The metal part 10 defines not only the outer wall of the package 100 but also the cavity. The bottom of the cavity is a chip-mounting surface 17 on which the SAW chip 40 is mounted. The backside of the SAW chip 40 is attached to the chip-mounting surface 17. Circuits are formed on the upper surface of the SAW chip 40 opposite to the backside thereof.

Multiple through holes 18 are formed in the metal part 10. The through holes 18 are arranged in two lines along the long-side edges of the SAW chip 40. The through holes 18 may be formed by press. The insulator part 30 is provided on the bottom of the package 100. The insulator part 30 is attached to the package 100 through fusing. The through holes 18 are completely full of the insulator part 30. The insulator part 30 slightly protrudes from the chip-mounting surface 17, and slightly extends inwards.

External terminals 20 are buried in the insulator part 30. The external terminals 20 penetrate through holes 18 in the buried state. The insulator part 30 is bonded to the external terminals 20 through fusing. The external terminals 20 are formed by shaping a plate-shaped metal member by pressing working. One ends of the external terminals are exposed to the cavity from the insulator part 30, and the other ends thereof form the bottom of the package 100. The bottom portions of the external terminals 20 are contact areas, which are brought into contact with terminals on a circuit board on which the package 100 is mounted. When the insulator part 30 is bonded to the metal part 10 through fusing, the external terminals 20 are straight. After bonding, both ends of the external terminals 20 are bent as shown. The contact areas of the external terminals 20 and the exposed surface of the insulator part 30 define the bottom of the package 100, that is, the bottom (mount surface) of the SAW device (indicated by the reference numeral 100 also). The bottom of the package 100 thus formed is almost flat uniformly. Ends of metal wires 50 are attached to exposed surfaces of the external terminals 20 in the cavity. The wires 50 may be attached to the external terminals 20 by thermo compression bonding or ultrasonic bonding. The other ends of the metal wires 50 are attached to pads on the circuit formation area on the SAW chip 40.

As shown in FIG. 1D, the SAW chip 40 has a piezoelectric substrate 12 on which comb-like electrodes (interdigital transducers: IDT) 13 and electrode pads 11 are formed by patterning. A SAW absorption material 14 is printed on the SAW chip 40 so as to sandwich both sides of the comb-like electrodes 13. Short-side ends of the piezoelectric substrate 12 are cut obliquely so as to have a given angle with respect to the SAW propagation direction. This is directed to preventing degradation of the filter characteristics due to reflection of the SAW at the ends of the piezoelectric substrate 12 that face each other in the propagation direction. The comb-like electrodes 13 are designed to have specific electrode finger pitches and specific weighted finger shapes in order to realize the desired filter performance. For example, the SAW chip 40 is 10 mm long and 2 mm wide, and may serve as a TV intermediate frequency filter in the band of 30 MHz to 75 MHz.

A lid 60 is formed by shaping a metal and is attached to a flange 16 formed along the edge of the outer wall of the package 100. The lid 60 hermetically seals the inside area of the package 100.

The metal part 10 of the package 100, the external terminals 20 and the lid 60 may be made of a metal such as SPC (cold-rolling steel sheet) industrially standardized, 42 alloy or KOVAR™. Preferably, these members are plated with Ni or Au. The insulator part 30 is made of an insulator such as glass or glass ceramics, which may easily be bonded to metal through fusing. The metal wires 50 may be made of Au or Al. The lid 60 may be joined to the flange 16 of the package 100 by resistive heat welding, seam welding, laser welding.

The package 100 may include at least the metal part 10 and the insulator part 30. The package 100 may be defined as a structure that includes not only the external terminals 20 but also the lid 60 in addition to the metal part 10 and the insulator part 30.

The SAW device mentioned above realizes hermetic sealing without any ceramic package in such a manner that the SAW chip 40 is die-mounted in the package formed by the less-expensive metal part 10 and insulator part 30. However, there are some disadvantages to be eliminated. There is difficulty in downsizing of the SAW device because the external terminals 20 for making external connections with the SAW chip 40 are arranged in two lines along the long-side edges of the chip 40. More specifically, the external terminals 20 are aligned along both sides of the SAW chip 40. A space as large as at least 1.0 mm is needed to insert one external terminal 20 into the through hole 18 formed in the metal part 10 of the package 100. Thus, only limited downsizing of the package 100 is available.

According to one aspect of the present invention, the external terminals 20 are arranged in a line along only one side of the SAW chip 40. Additionally, the present invention takes into consideration a possibility that solder bonding of the terminals 20 to a printed-circuit board may be damaged due to mechanical shock or the like. This is because the single-side line arrangement of the external terminals 20 causes unbalanced fixing of the SAW device to the printed-circuit board. First through third embodiments of the present invention described below have unique arrangements in which dummy external terminals isolated from the SAW device 40 are provided in addition to the single line arrangement of the regular external terminals 20 for making external connections.

(First Embodiment)

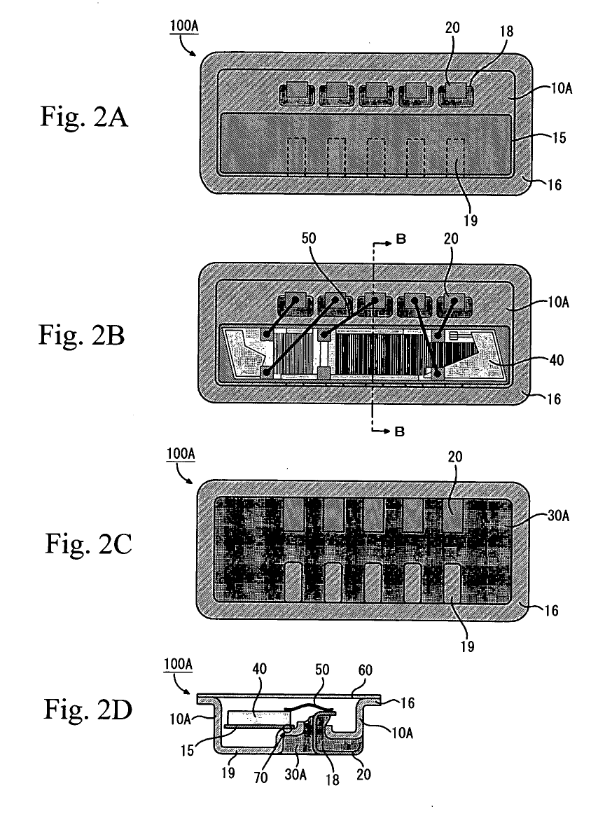

FIGS. 2A through 2D illustrate a SAW device according to a first embodiment of the present invention. More particularly, FIG. 2A shows a plan view of a package of the SAW device. FIG. 2B is a plan view of the SAW device while seeing through the cap. FIG. 2C is a bottom view of the SAW device. FIG. 2D is a cross-sectional view taken along a line B-B′ shown in FIG. 2B. In these figures, parts that are the same as those shown in FIGS. 1A through 1D are given the same reference numerals as previously.

The present SAW device is an electronic device, which includes a package 100A and the SAW chip 40. The package 100A is made up of a metal part 10A and an insulator part 30A. The metal part 10A is defined by processing a metal plate. The insulator part 30A is bonded to the metal part 10A through fusing. The SAW device has first external terminals 20 for making external connections, and a plate member 15. The first external terminals 20 are electrically connected to the SAW chip 40, and are aligned in such a state that the first external terminals 20 are buried in the insulator part 30A. The plate member 15 supports the SAW chip 40. The metal part 10A has recess portions 19, which serve as second external terminals. The plate member 15 is provided so as to cover the recess portions 19.

More specifically, the present SAW device has the package 100A and the SAW chip 40, which chip is hermetically sealed in the package 10A. The package 100A has the metal part 10A and the insulator part 30A. The SAW chip 40 is housed in a cavity of the package 100A. A metal member is shaped into the metal part 10A by press (extrusion press). The metal part 10A defines the most of the package 10A. The metal part 10A has the multiple recess portions 19. The “recess” is observed from the inside of the package, while it is a projection when it is viewed from the outside of the package 100A. Each recess portion 19 has a cross section similar to a C shape. The recess portions 19 may be formed with presswork. The recess portions 19 have flat bottom surfaces, which serve as areas for making external connections. The recess portions 19 serve as second external terminals. Thus, reference numeral 19 is also assigned to the second external terminals. The second external terminals 19 form portions of the package 100A, and portions of the metal part 10A. The second external terminals 19 are not connected to the SAW chip 40 but function as ground terminals of the package 100A. When the SAW device is mounted on the print-circuit board, the second external terminals 19 are at an identical potential (ground potential). The second external terminals 19 are not connected to the SAW chip 40 directly, and thus serve as dummy terminals.

The second external terminals 19 are arranged in symmetry with the first external terminals 20. The first external terminals 20 are arranged in a line along a first long-side edge of the package 100A. The second external terminals 19 are arranged in a line along a second long-side edge of the package 100A opposite to the first long-side edge. The first external terminals 20 penetrate through the holes 18 formed in the metal part 10A, whereas the second external terminals 19 do not need the through holes 18. That is, the metal part 10A of the package 100A is required to have only one line of through holes 18. As shown in FIG. 2A, the through holes 18 are formed along only one side of the SAW chip 40. The second external terminals 19 are located below the SAW chip 40. It can be seen from the above that the package 100A has short-side edges shorter than those of the package shown in FIGS. 1A through 1D.

The plate member 15 is a metal plate that has almost the rectangular shape, and is provided so as to cover the recess portions 19. The plate member 15 is welded and fixed to the inner surface of the metal part 10A of the package 100A at joining positions 70. The plate member 15 is provided to define a flat area on which the SAW chip 40 is die-mounted with an adhesive. Terminals on the SAW chip 40 and the first external terminals 20 are electrically connected by metal thin wires 50. Thermo compression bonding or ultrasonic bonding may be used to bond the wires 50. In order to enhance the reliability of electrical connections with the metal thin wires 50, preferably, the connecting areas of the first external terminals 20 are substantially equal to the terminals of the SAW chip 40 in height. More specifically, it is preferable to have a difference in height within the range of ±50 μm.

The insulator part 30A forms a part of the bottom of the package 100A. The insulator part 30A is bonded to the bottom of the package 100A through fusing. The insulator part 30A completely fills in the through holes 18. The insulator part 30A slightly protrudes from the through holes 18 to the inside of the package 100A.

The first external terminals 20 are buried in the insulator part 30A, and penetrate through the through holes 18 arranged in a line. The insulator part 30A is bonded to the first external terminals 20 through fusing. The first external terminals 20 may be defined by pressing a metal plate. The first external terminals 20 have ends that protrude from the insulator part 30A to the cavity, and the other ends that define the bottom of the package 100A. The bottom portions of the package 100A defined by the first external terminals 20 are used to make external connections. When the insulator part 30A is fused for bonding to the metal part 10A, the first external terminals 20 are straight. After the insulator part 30A is bonded to the metal part 10A, both ends of the first external terminals 20 are bent as shown in FIG. 2D. Thus, the inner surfaces of the first external terminals 20 are not bonded to the insulator part 30A but slight gaps are formed therebetween. The contact areas of the first external terminals 20, the exposed surfaces of the insulator parts 30A, and the second external (dummy) terminals 19 define the bottom of the package 100A, that is, the bottom (mounting surface) of the SAW device also indicated by the reference numeral 100A. The bottom thus formed is almost flat.

The metal part 10A of the package 100A, the external terminals 20, the lid 60 and the plate member 15 may be made of a metal such as SPC (cold-rolling steel sheet) industrially standardized, 42 alloy or KOVART™. Preferably, these members are plated with Ni or Au. The insulator part 30A is made of an insulator such as glass or glass ceramics, which is easily bonded to metal through fusing.

According to the first embodiment of the present invention, the package can be downsized and the SAW device can be mounted on the printed-circuit board or the like with high reliability and stability.

It is not necessarily required that the second external terminals (recessed portions) 19 are symmetrically arranged with the first external terminals 20. An asymmetrical arrangement may be employed as long as the mount stability is maintained. For example, two of the five external terminals 19 may be omitted. In FIG. 2A, the second external terminals 19 face the first external terminals 20. Alternatively, a zigzag arrangement may be employed. Any element or chip of the backside mounting type may be die-mounted in place of the SAW device 40. In FIG. 2C, the second external terminals 19 have the areas for making external connections as large as those of the first external terminals 20. However, the second external terminals 19 may have a different contact area from that of the first external terminals 20.

(Second Embodiment)

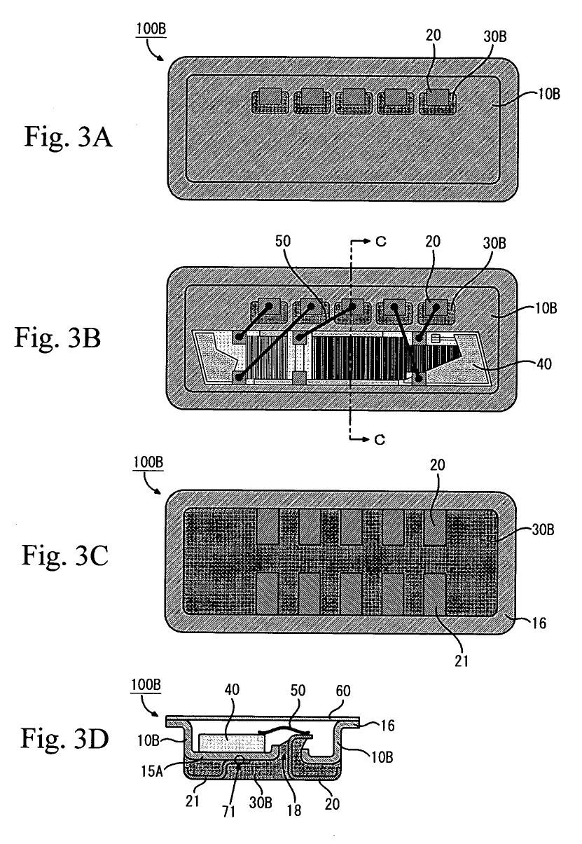

FIGS. 3A through 3D illustrate a SAW device according to a second embodiment of the present invention. More particularly, FIG. 3A shows a plan view of a package of the SAW device. FIG. 3B shows the inside of the SAW device while seeing through a cap. FIG. 3C is a bottom view of the SAW device, and FIG. 3D is a cross-sectional view taken along a line that corresponds to the line C-C′ in FIG. 3B. In these figures, parts that are the same as those shown in the previously described figures are given the same reference numerals as previously. The second embodiment differs from the first embodiment in the following. First, the second embodiment employs second external terminals formed by a material different from the metal part of the package, while the first embodiment employs the second terminals formed by the metal part 10A of the package. Second, the second embodiment has the SAW chip directly attached to the metal part of the package, while the first embodiment employs the plate member 15 for mounting the SAW chip.

The second embodiment is directed to an electronic device composed of a package 100B and the SAW chip 40 housed in the package 100B. The package 100B has a metal part 100B and an insulator part 30B. A metal member may be shaped into the metal part 10B by press or another appropriate method. The electronic device, namely, SAW device has the first external terminals 20, and second external terminals 21. The first external terminals 20 are buried in the insulator part 30B, and are aligned. The second external terminals 21 are attached to the outer surface of the metal part 10B. The SAW chip 40 is attached to the inner surface of the metal part 10B, and faces the second external terminals 21 through the metal part 10B.

More particularly, the present SAW device has the package 100B and the SAW chip 40, which chip is hermetically sealed in the package 100B. The package 100B has the metal part 10B and the insulator part 30B. The SAW chip 40 is housed in a cavity of the package 100B. A metal member is shaped into the metal part 10B by press (extrusion press). The metal part 10B defines the most of the package 100B. The metal part 10B has a flat chip mounting area 15A, which may be shaped by press work. The chip mounting area 15A has a flat outer surface, to which the second external terminals 21 are attached by welding or the like. The second external terminals 21 are not connected to the SAW chip 40, and serve as ground terminals. The second external terminals 21 have portions having an approximately L-shaped cross section, and are electrically and mechanically connected to the metal part 10B at joining positions 71. When the SAW device is mounted on the print-circuit board, the second external terminals 21 are at an identical potential (ground potential). The second external terminals 21 are not connected to the SAW chip 40, and thus serve as dummy terminals.

The second external terminals 21 may be separate members. However, it is preferable to form the terminals 21 by a single-piece member. A single metal member is shaped by press into the second external terminals 21 and a flat part that connects the terminals 21. The single electrode member thus formed reduces the number of parts used in the SAW device and the number of work steps of the manufacturing process. The single electrode member will also be employed in a third embodiment of the present invention that will be described later.

The second external terminals 21 are partially buried in the insulator part 30B and are bonded thereto through fusing. The second external terminals 21 have exposed portions, which serve as contact areas. When the insulator part 30B is bonded to the metal part 10B through fusing, the first external terminals 20 and the second external terminals 21 are kept straight. After the insulator part 30B is bonded to the metal part 10B, the first and second external terminals 20 and 21 are bent, as shown in FIG. 3D. Thus, the inner surfaces of the first external terminals 20 thus bent are not bonded to the insulator part 30B but are slightly spaced apart therefrom. Similarly, the inner surfaces of the second external terminals 21 thus bent are not bonded to the insulator part 30B but are slightly spaced apart therefrom. The contact areas of the first external terminals 20, the exposed areas of the insulator part 30B, and the contact areas of the second external terminals 21 form the bottom of the package 100B, in other words, the bottom (mounting surface on the print-circuit board) of the SAW device, which is also indicated by the reference numeral 100A. The bottom thus formed is almost flat.

The second external terminals 21 are arranged in symmetry with the first external terminals 20. The first external terminals 20 are arranged in a line along a first long-side edge of the package 100B. The second external terminals 21 are arranged in a line along a second long-side edge of the package 100B opposite to the first long-side edge. The first external terminals 20 penetrate through the holes 18 formed in the metal part 10B, whereas the second external terminals 21 do not need the through holes 18. That is, the metal part 10B of the package 100B is required to have only one line of through holes 18. As shown in FIG. 3A, the through holes 18 full of the insulator part 30B are formed along only one side of the SAW chip 40. The second external terminals 21 are located below the SAW chip 40. It can be seen from the above that the package 100B has short-side edges shorter than those of the package shown in FIGS. 1A through 1D.

The terminals on the SAW chip 40 and the first external terminals 20 are electrically connected by metal thin wires 50. Thermo compression bonding or ultrasonic bonding may be used to bond the wires 50. In order to enhance the reliability of electrical connections with the metal thin wires 50, preferably, the connecting areas of the first external terminals 20 are substantially equal to the terminals of the SAW chip 40 in height. More specifically, it is preferable to have a difference in height within the range of ±50 μm.

The lid 60 is formed by shaping a metal and is attached to the flange 16 formed along the edge of the outer wall of the package 100B. The lid 60 hermetically seals the inside area of the package 100B.

The metal part 10A of the package 100B, the first external terminals 20, the second external terminals 21, and the lid 60 may be made of a metal such as SPC industrially standardized, 42 alloy or KOVART™. Preferably, these members are plated with Ni or Au. The insulator part 30B is made of an insulator such as glass or glass ceramics, which may easily be bonded to metal through fusing.

According to the second embodiment of the present invention, the package can be downsized and the SAW device can be mounted on the printed-circuit board or the like with high reliability and stability.

It is not necessarily required that the second external terminals (recessed portions) 21 are symmetrically arranged with the first external terminals 20. An asymmetrical arrangement may be employed as long as the mount stability is maintained. For example, two of the five external terminals 21 may be omitted. In FIG. 3C, the first external terminals 20 face the second external terminals 21. Alternatively, a zigzag arrangement may be employed. Any element or chip of the backside mounting type may be die-mounted in place of the SAW device 40. In FIG. 3C, the second external terminals 21 have the areas for making external connections as large as those of the first external terminals 20. However, the second external terminals 21 may have a different contact area from that of the first external terminals 20.

(Third Embodiment)

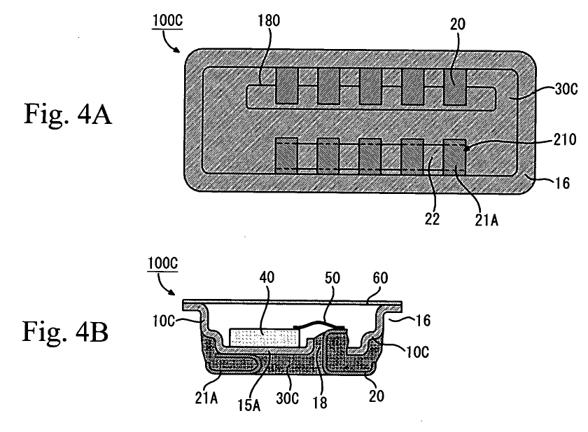

FIGS. 4A and 4B show a SAW device according to a third embodiment of the present invention. More particularly, FIG. 4A is a bottom view of the SAW device in a state in which the insulator part has been removed, and FIG. 4B is a cross-sectional view taken along a line running in the short-side direction. The SAW device has the SAW chip 40 and the metal thin wires 50. In FIGS. 4A and 4B, parts that are the same as those shown in the previously described figures are given the same reference numerals. The SAW device shown in FIGS. 4A and 4B corresponds to a variation of the SAW device shown in FIGS. 3A through 3D. More particularly, the SAW device shown in FIGS. 4A and 4B is equipped with second external terminals formed by a single-piece member, and a single through hole is provided in common to the first external terminals 20.

The SAW device has a package 100C and the SAW chip 40 housed therein. The package 100C has a metal part 10C and an insulator part 30C fused and then bonded thereto. The first terminals 20 electrically coupled to the chip 40 are buried in the insulator part 30C and are arranged in a line. Second terminals 21A are attached to an outer surface of the metal part 10C. The chip 40 is attached to an inner surface of the metal part 10C, and faces the second external terminals 21A through the flat chip mounting area 15A.

The second external terminals 21A are parts of a single-piece electrode member 210. The member 210 has a flat portion 22 and the second external terminals 21A that stand vertically from the flat portion 22 and extend above the flat portion 22. The flat portion 22 is welded to the outer surface of the chip mounting area 15A at several positions. The second external terminals 21A have a cross-section similar to a C shape or U shape. A metal material may be shaped into the electrode member 210 by press.

A single through hole 180 is formed in the metal part 10C of the package 100C. The single through hole 180 is substituted for the multiple through holes 18 employed in the first and second embodiments. The insulator part 30C is provided so that the through hole 180 is filled therewith. The first terminals 20 are buried in the insulator part 30C and are bonded thereto through fusing. The contact areas of the second external terminals 21A are exposed from the insulator part 30C. Similarly, the contact areas of the first external terminals 20 are exposed from the insulator part 30C. These contact areas and the bottom surface of the insulator part 30C form the flat bottom of the package 100C.

The second external terminals 21A are not connected to the SAW chip 40, and serve as ground terminals of the package 100C. In this regard, it may be said the second external terminals 21A are dummy terminals.

The metal part 10C of the package 100C, the first external terminals 20, the second external terminals 21A and the lid 60 may be made of a metal such as SPC industrially standardized, 42 alloy or KOVAR™. Preferably, these members are plated with Ni or Au. The insulator part 30C is made of an insulator such as glass or glass ceramics, which may easily be bonded to metal through fusing.

According to the third embodiment of the present invention, the package can be downsized and the SAW device can be mounted on the printed-circuit board or the like with high reliability and stability.

It is not necessarily required that the second external terminals 21A are symmetrically arranged with the first external terminals 20. An asymmetrical arrangement may be employed as long as the mount stability is maintained. For example, two of the five external terminals 21A may be omitted. In FIG. 4A, the second external terminals 21A face the first external terminals 20. Alternatively, a zigzag arrangement may be employed. Any element or chip of the backside mounting type may be die-mounted in place of the SAW device 40. In FIG. 4A, the second external terminals 21A have the areas for making external connections as large as those of the first external terminals 20. However, the second external terminals 21A may have a different contact area from that of the first external terminals 20.

The present invention is not limited to the specifically disclosed embodiments, and other embodiments, variations and modifications may be made without departing from the scope of the present invention.

The present invention is based on Japanese Patent Application No. 2003-099964 filed on Apr. 3, 2003, the entire disclosure of which is hereby incorporated by reference.

What is claimed is:

1. An electronic device comprising:
a package having a metal part shaped by pressing a metal member, and an insulator part bonded to the metal part through fusing;
a chip housed in the package;
first terminals electrically connected to the chip and buried in the insulator part so as to be arranged in a line; and
a plate member that supports the chip from a backside thereof,
the metal parts having recess portions that define second external terminals,
the plate member being provided so as to cover the recess portions.

2. The electronic device as claimed in claim 1, wherein:
the first external terminals are arranged in a line along a first side of the package; and
the second external terminals are arranged in a line along a second side of the package opposite to the first side.

3. The electronic device as claimed in claim 1, wherein the recess portions, the insulator part and the first terminals form a surface of the electronic device.

4. The electronic device as claimed in claim 1, wherein the plate member is attached to the metal part.

5. The electronic device as claimed in claim 1, wherein the backside of the chip is attached to the plate member.

6. The electronic device as claimed in claim 1, wherein the plate member is a metal member.

7. The electronic device as claimed in claim 1, wherein the metal part has through holes in which the insulator part is provided.

8. The electronic device as claimed in claim 1, wherein:
the first terminals have parts to which metal wires are attached for making connections with terminals of the chip; and
the parts of the first terminals being flush with the terminals of the chip.

9. The electronic device as claimed in claim 1, wherein the first and second external terminals have a symmetrical arrangement.

10. The electronic device as claimed in claim 1, wherein the first and second external terminals have an asymmetrical arrangement.

11. The electronic device as claimed in claim 1, wherein the first external terminals have contact areas that are identical to or different from those of the second external terminals.

12. The electronic device as claimed in claim 1, wherein the second external terminals are ground terminals and are not connected to the chip.

13. The electronic device as claimed in claim 1, wherein the insulator part comprises glass.

14. The electronic device as claimed in claim 1, wherein the chip is a surface acoustic wave chip.

15. The electronic device as claimed in claim 1, wherein:
the package has a flange that is a part of the metal part; and
the electronic device further comprises a cap attached to the flange.

16. An electronic device comprising:
a package having a metal part shaped by pressing a metal member, and an insulator part bonded to the metal part through fusing;
a chip housed in the package;
first terminals electrically connected to the chip and buried in the insulator part so as to be arranged in a line; and
second terminals attached to an outer surface of the metal part,
the chip being attached to an inner surface of the metal surface and facing the second external terminals through the metal part.

17. The electronic device as claimed in claim 16, wherein the second external terminals are partially buried in the insulator part.

18. The electronic device as claimed in claim 16, wherein the second external terminals are partially located on the insulator part.

19. The electronic device as claimed in claim 16, wherein the second external terminals are parts of a single-piece member.

20. The electronic device as claimed in claim 16, wherein the second external terminals are welded to the metal part.

21. A package comprising:
a metal part shaped by pressing a metal member;
an insulator part bonded to the metal part through fusing;
first terminals electrically connected to a chip and buried in the insulator part so as to be arranged in a line; and
a plate member that supports the chip from a backside thereof,
the metal parts having recess portions that define second external terminals,
the plate member being provided so as to cover the recess portions.

22. A package comprising:
a metal part shaped by pressing a metal member;
an insulator part bonded to the metal part through fusing;
first terminals electrically connected to a chip and buried in the insulator part so as to be arranged in a line; and
second terminals attached to an outer surface of the metal part,
the chip being attached to an inner surface of the metal surface and facing the second external terminals through the metal part.
